(19) United States
(12) Patent Application Publication
(10) Pub. No.: US 2025/0285924 A1
(43) Pub. Date: Sep. 11, 2025

(54) SEMICONDUCTOR DEVICE

(71) Applicant: Mitsubishi Electric Corporation, Tokyo (JP)

(72) Inventor: Yu FUKUNAGA, Tokyo (JP)

(73) Assignee: Mitsubishi Electric Corporation, Tokyo (JP)

(21) Appl. No.: 19/031,309

(22) Filed: Jan. 17, 2025

(30) Foreign Application Priority Data
Mar. 6, 2024 (JP) 2024-033755

(51) Int. Cl. H01L 23/06; H01L 23/00; H01L 23/053; H01L 23/31; H01L 25/065

(52) U.S. Cl. CPC H01L 23/06; H01L 23/053; H01L 23/3121; H01L 24/45; H01L 24/48; H01L 25/0655; H01L 2224/45124; H01L 2224/45139; H01L 2224/45144; H01L 2224/48091; H01L 2224/48137; H01L 2224/48225; H01L 2924/1815

(57) ABSTRACT

The semiconductor device includes a substrate, a semiconductor element, a case, a sealing resin, and a lid. The semiconductor element is connected onto the substrate. The case houses the substrate and the semiconductor element. The sealing resin seals the semiconductor element in the case. The lid is disposed in the case and covers the sealing resin from the top thereof. The lid is made of both a resin material and a metal material mixed in the resin material.

### CROSS REFERENCE TO RELATED APPLICATIONS

This non-provisional application is based on Japanese Patent Application No. 2024-033755 filed on Mar. 6, 2024 with the Japan Patent Office, the entire contents of which are hereby incorporated by reference.

### BACKGROUND OF THE INVENTION

### Field of the Invention

The present disclosure relates to a semiconductor device.

### Description of the Background Art

When a power semiconductor module is in use, a large current flows therethrough, which generates a large amount of heat. Therefore, it is important to improve heat dissipation of the power semiconductor module. For example, Japanese Patent Laying-Open No. 2018-182220 discloses a technology to dissipate heat generated by semiconductor elements through a heat sink.

### SUMMARY OF THE INVENTION

As a power semiconductor module, a case-sealed semiconductor module and a mold-sealed semiconductor module may be given. In general, a case-sealed semiconductor module has a sealing lid. The lid may prevent heat generated by the semiconductor element from being released to the outside. Japanese Patent Application Laid-Open No. 2018-182220 discloses a mold-sealed semiconductor module. However, Japanese Patent Laying-Open No. 2018-182220 does not propose any technology to improve heat dissipation of a case-sealed semiconductor module.

The present disclosure has been made to solve the above problem. An object of the present disclosure is to provide a case-sealed semiconductor device capable of improving heat dissipation.

A semiconductor device according to a first aspect of the present disclosure includes a substrate, a semiconductor element, a case, a sealing resin, and a lid. The semiconductor element is connected onto the substrate. The case houses the substrate and the semiconductor element. The sealing resin seals the semiconductor element in the case. The lid is disposed in the case and covers the sealing resin from the top thereof. The lid is made of both a resin material and a metal material mixed in the resin material.

A semiconductor device according to a second aspect of the present disclosure includes a substrate, a semiconductor element, a case, a sealing resin, and a lid. The semiconductor element is connected onto the substrate. The case houses the substrate and the semiconductor element. The sealing resin seals the semiconductor element in the case. The lid is disposed in the case and covers the sealing resin from the top thereof. The lid contains a resin material and carbon fibers in a proportion of 10% by mass or more and 20% by mass or less of the entire lid.

A semiconductor device according to a third aspect of the present disclosure includes a substrate, a semiconductor element, a case, a sealing resin, and a lid. The semiconductor element is connected onto the substrate. The case houses the substrate and the semiconductor element. The sealing resin seals the semiconductor element in the case. The lid is disposed in the case and covers the sealing resin from the top thereof. The main component of the lid is a resin material. The resin material includes a filler. The filler has polarity, and the filler is arranged in such a manner that the molecules thereof are oriented in a predetermined direction.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view illustrating a semiconductor device according to the present embodiment;

FIG. 2 is a schematic cross-sectional view illustrating a step of arranging a lid in a manufacturing process of the semiconductor device of FIG. 1;

FIG. 3 is a schematic diagram illustrating a configuration of a lid according to the first embodiment;

FIG. 4 is a schematic diagram illustrating a configuration of a lid according to a third embodiment;

FIG. 5 is a schematic view illustrating a lid in the state of a raw material according to a fourth embodiment; and

FIG. 6 is a schematic view illustrating a configuration of the lid after completion according to the fourth embodiment.

### DESCRIPTION OF THE PREFERRED EMBODIMENTS

### First Embodiment

### <Configuration of Semiconductor Device>

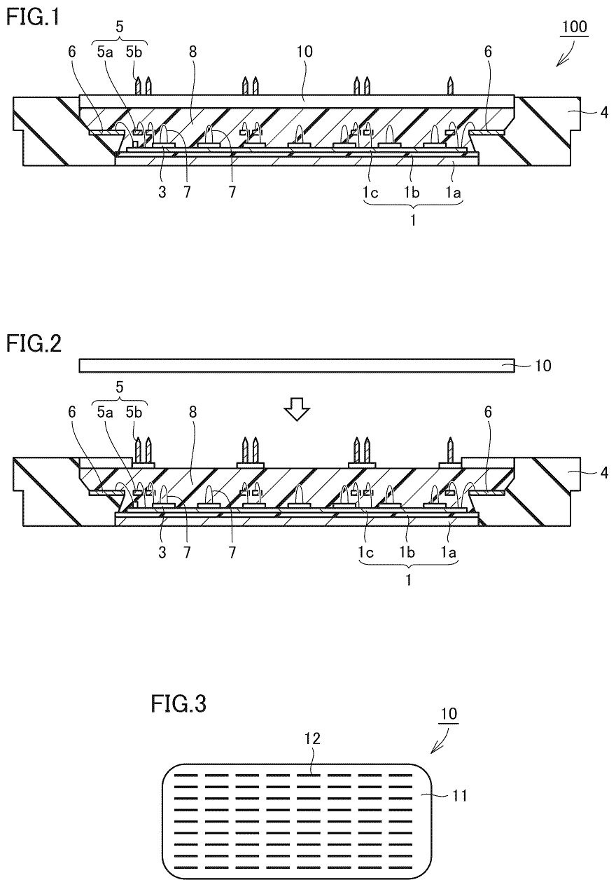

FIG. 1 is a schematic cross-sectional view illustrating a semiconductor device according to the present embodiment. As illustrated in FIG. 1, a semiconductor device 100 according to the present embodiment is a so-called power semiconductor module. The semiconductor device 100 includes a substrate 1. The substrate 1 includes a base 1a, an insulating layer 1b, and an electrode plate 1c. The insulating layer 1b is stacked on the base 1a. The electrode plate 1c is stacked on the insulating layer 1b.

The base 1a has, for example, a rectangular planar shape, and has a substantially constant thickness in the vertical direction in FIG. 1. Hereinafter, such a shape will be referred to as a flat plate shape. The base 1a is made of metal. For example, the base 1a is made of copper or aluminum. The insulating layer 1b has a flat plate shape. The insulating layer 1b is made of a resin material or a ceramic material. More specifically, the ceramic material for the insulating layer 1b may be, for example, any of alumina (Al₂O₃), aluminum nitride (AlN), and silicon nitride (Si₃N₄). The insulating layer 1b may be an insulating substrate. The electrode plate 1c is made of, for example, copper or aluminum. The electrode plate 1c has a flat plate shape. The electrode plate 1c functions as a circuit pattern. The electrode plate 1c may be connected onto the insulating layer 1b by soldering.

A semiconductor chip 3 is connected onto the substrate 1 as a semiconductor element. The semiconductor chip 3 is smaller in size than the substrate 1 in plan view. Thus, a plurality of semiconductor chips 3 are spaced apart from each other and connected onto the substrate 1. The semiconductor chip 3 has a flat plate shape. The semiconductor chip 3 is mounted on the substrate 1, and in particular on the electrode plate 1c by soldering. The semiconductor chip 3 is an IGBT (Insulated Gate Bipolar Transistor) chip or a diode chip.

The substrate 1 and the semiconductor chip 3 are housed in a case 4. The case 4 is disposed to surround the substrate 1 and the semiconductor chip 3 in plan view. The case 4 is made of an insulating material having high mechanical strength and high insulating property. The case 4 is made of a generally known PPS (Poly Phenylene Sulfide Resin) or liquid crystal polymer. At least a part of the substrate 1 (for example, the insulating layer 1b and the electrode plate 1c) is housed in the case 4. However, the lower surface (opposite to the surface to which the insulating layer 1b is connected) of the base 1a of the substrate 1 may be exposed from the case 4.

A terminal 5 may be disposed in the case 4. The terminal 5 is spaced apart from the semiconductor chip 3. The terminal 5 is made of copper, an alloy of copper, or the like. The terminal 5 includes a first portion 5a and a second portion 5b. The first portion 5a is housed in the case 4. The second portion 5b is disposed to protrude to the outside of the case 4. In other words, the terminal 5 extends from the inside of the case 4 to the outside thereof. Thus, the terminal 5 electrically connects the semiconductor device 100 to an external device.

A pad 6 is formed on a part of an inner wall surface of the case 4 closer to the substrate 1 or the like housed in the case. As illustrated in FIG. 1, for example, when the inner wall surface of the case 4 has a step, the pad 6 may be formed on a portion of the step extending in the horizontal direction. The pad 6 is a thin film made of a conductive material such as copper or aluminum.

A plurality of wires 7 are bonded to an upper surface of the semiconductor chip 3. The wire 7 is made of gold, silver, copper, or aluminum. The wire 7 electrically connects the plurality of semiconductor chips 3 to each other. The wire 7 electrically connects one semiconductor chip 3 to the first portion 5a. The wire 7 may electrically connect one semiconductor chip 3 to the pad 6. The wire 7 may electrically connect the electrode plate 1c to the first portion 5a.

The semiconductor chip 3 is sealed in the case 4 by a sealing resin 8. The sealing resin 8 is, for example, an epoxy resin. In addition to the semiconductor chip 3, the sealing resin 8 seals the insulating layer 1b, the electrode plate 1c, and the first portion 5a of the terminal 5 of the substrate 1. At least a part of the terminal 5 is embedded in the sealing resin 8.

A lid 10 is disposed in the case 4. The lid 10 covers the sealing resin 8 from the top thereof. In other words, the lid 10 is disposed to be in contact with an upper surface of the sealing resin 8. The lid 10 has a flat plate shape. A part of the lid 10 may be provided with a through hole for the terminal 5 to pass through.

FIG. 2 is a schematic cross-sectional view illustrating a step of arranging a lid in a manufacturing process of the semiconductor device of FIG. 1. As illustrated in FIG. 2, in the manufacturing process of the semiconductor device 100 of FIG. 1, the following steps are performed. The insulating layer 1b is connected onto the base 1a by a bonding material. “Connected onto the base 1a” means “connected onto a main surface, i.e., an upper surface of the base 1a”. The same applies to the following description. The electrode plate 1c is connected onto the insulating layer 1b by a bonding material such as solder. A plurality of semiconductor chips 3 are spaced apart from each other and connected onto the electrode plate 1c by solder. As described above, the semiconductor chips 3 are connected onto the substrate 1 and are housed in the case 4. As illustrated in FIG. 2, after the terminals 5 have been installed in the case 4, the sealing resin 8 is injected into the case 4. At this time, the sealing resin 8 is in a liquid state and is not solidified.

After the sealing resin 8 is injected, the lid 10 is mounted on the sealing resin 8 in the case 4. After the lid 10 is mounted, the sealing resin 8 is heated and cured. Therefore, the lid 10 and the sealing resin 8 become integrated.

FIG. 3 is a schematic diagram illustrating a configuration of a lid according to the first embodiment. As illustrated in FIG. 3, the lid 10 according to the present embodiment is made of both a resin material 11 and a metal material 12. The metal material 12 is mixed in the resin material 11. The lid 10 is mainly made of the resin material 11. In other words, the shape of the lid 10 is formed by the resin material 11. The resin material 11 is, for example, PPS (Poly Phenylene Sulfide Resin). The metal material 12 is uniformly mixed in the resin material 11 constituting the lid 10. As illustrated in FIG. 3, the metal material 12 may be in the form of fine fibers extending in the left-right direction, for example. However, the metal material 12 is not limited to the form illustrated in FIG. 3, and may be in the form of fine fibers extending in the vertical direction or an oblique direction in the drawing, for example. The metal material 12 may be arranged to extend along the thickness direction of the lid 10 (perpendicular to the paper surface of FIG. 3). The extending direction of the metal materials 12 may be different for each metal material 12. A portion of the plurality of metal materials 12 may be in contact with each other. Alternatively, the metal material 12 may be fine grains or spheres. If the metal materials 12 are localized in a partial region of the resin material 11, stress concentration occurs in the partial region when the lid 10 is deformed by heat. This may cause cracking or breaking to occur in the lid 10. From the viewpoint of suppressing this problem, preferably the metal materials 12 are uniformly spread (dispersed) in the entire lid 10. Although FIG. 3 illustrates that the extending direction of the plurality of fibrous metal materials 12 is oriented in one direction, the extending directions of the plurality of metal materials 12 may be different from each other.

In the manufacturing process of the lid 10 having the configuration illustrated in FIG. 3, the resin material 11 and the metal material 12 are mixed so that the metal material 12 is embedded in the resin material 11. Any conventionally known method may be employed to mix the resin material 11 and the metal material 12. Thereafter, the resin material 11 containing the metal material 12 is molded. Thus, the lid 10 is obtained. Thus, as illustrated in FIG. 3, a large number of fine metal materials 12 are spaced apart from each other and are uniformly dispersed in the resin material 11.

The fact that the lid 10 contains the resin material 11 and the metal material 12 may be confirmed by the following method. First, the lid 10 is pulverized. The substances contained in the obtained powder may be measured by any commonly known method. The commonly known method may include, for example, infrared spectroscopy and differential scanning calorimetry. Alternatively, the substances contained in the powder may be qualitatively evaluated and quantitatively evaluated by a nuclear magnetic resonance method.

### <Effects>

The semiconductor device 100 according to the present embodiment includes a substrate 1, a semiconductor chip 3, a case 4, a sealing resin 8, and a lid 10. The semiconductor chip 3 is connected onto the substrate 1. The case 4 houses the substrate 1 and the semiconductor chip 3. The sealing resin 8 seals the semiconductor chip 3 in the case 4. The lid 10 is disposed in the case 4 and covers the sealing resin 8 from the top thereof. The lid 10 is made of both a resin material 11 and a metal material 12 mixed in the resin material 11.

In general, the metal material 12 has a higher thermal conductivity than the resin material 11 such as PPS. For example, the thermal conductivity of PPS is 0.29 W/(m·K). On the other hand, the thermal conductivity of aluminum, for example, is 226 W/(m·K). Therefore, the thermal conductivity of a lid 10 containing the metal material 12 is higher than that of a lid 10 containing only the resin material 11. Thus, in a power semiconductor module as an example of the case-sealed semiconductor device 100, heat generated by the semiconductor chip 3 can be efficiently dissipated to the outside through the lid 10. In other words, the heat dissipation of the entire semiconductor device 100 can be improved.

In the manufacturing method of the present embodiment, after the lid 10 is mounted on the liquid sealing resin 8, the sealing resin 8 is heated and cured. Thus, the lid 10 and the sealing resin 8 become integrated. By integrating the lid 10 and the sealing resin 8, heat generated by the semiconductor chip 3 can be efficiently released to the outside through the sealing resin 8 and the lid 10.

### Second Embodiment

In each of the following embodiments, the difference from the first embodiment will be mainly described. In other words, in each of the following embodiments, the features such as the configuration, the material, the manufacturing method, and the evaluation method similar to those of the first embodiment will not be repeated in principle.

### <Configuration of Semiconductor Device>

The lid 10 of the semiconductor device 100 according to the present embodiment has a configuration in which the metal material 12 is mixed in the resin material 11, which is the same as that in the first embodiment. However, the lid 10 in the present embodiment contains at least one of copper and aluminum in a proportion of 10% by mass or more and 30% by mass or less of the entire lid 10. “10% by mass or more and 30% by mass or less of the entire lid 10” means 10% by mass or more and 30% by mass or less when the entire lid 10 is set to 100% by mass.

Any one of copper and aluminum may be contained in the entire lid 10 in a proportion of 10% by mass or more and 30% by mass or less. Alternatively, both copper and aluminum may be contained in the lid 10 as long as the total amount thereof is 10% by mass or more and 30% by mass or less of the entire lid 10.

The manufacturing process of the lid 10 according to the present embodiment is the same as that of the first embodiment. Specifically, the resin material 11 and the metal material 12 are mixed. The mass of either one of copper and aluminum or the total mass of both is adjusted to be 10% by mass or more and 30% by mass or less with respect to the mass of the entire lid 10. The mixed material is then molded.

### <Effects>

In the semiconductor device 100 according to the present embodiment, the lid 10 may contain at least one of copper and aluminum in a proportion of 10% by mass or more and 30% by mass or less of the entire lid 10. Accordingly, the same effects as those of the first embodiment may be obtained. By containing the above-described materials, the lid 10 can be manufactured to have sufficient heat dissipation. In addition, by containing the above-described materials in the above-described proportion, the lid 10 can be manufactured to have sufficient heat dissipation at low cost. Specifically, according to the present embodiment, the thermal conductivity of the lid can be improved by about 4 to 5 times as compared to a lid made of only the resin material 11 and having the same shape and the same dimension.

### Third Embodiment

### <Configuration of Semiconductor Device>

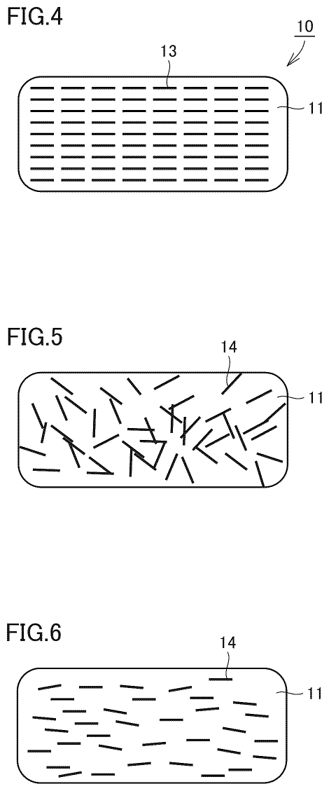

FIG. 4 is a schematic diagram illustrating a configuration of a lid according to a third embodiment. As illustrated in FIG. 4, the lid 10 of the present embodiment contains a resin material 11 and carbon fibers 13. The lid 10 of the present embodiment may or may not contain the metal material 12 of the first and second embodiments. The carbon fibers 13 are contained in a proportion of 10% by mass or more and 20% by mass or less of the entire lid 10.

The manufacturing process of the lid 10 of the present embodiment is the same as that of the first and second embodiments. In other words, the resin material 11 and the carbon fibers 13 are mixed as raw materials before molding. The fine carbon fibers 13 are mixed by the above-described mass ratio. Thereafter, the resin material 11 is molded. Thus, the lid 10 is obtained. As a result, as illustrated in FIG. 4, a large number of fine carbon fibers 13 are spaced apart from each other and are uniformly dispersed in the resin material 11. As illustrated in FIG. 4, the carbon fibers 13 may be in the form of fine fibers extending in the left-right direction, for example. However, the carbon fibers 13 are not limited to the form illustrated in FIG. 4, and may be fine fibers extending in the vertical direction or an oblique direction in the drawing, for example. The carbon fibers 13 may be arranged to extend along the thickness direction of the lid 10 (perpendicular to the paper surface of FIG. 4). Alternatively, the extending direction of the short carbon fibers 13 may be different for each carbon fiber 13. A portion of the plurality of carbon fibers 13 may be in contact with each other.

### <Effects>

The semiconductor device 100 according to the present embodiment includes a substrate 1, a semiconductor chip 3, a case 4, a sealing resin 8, and a lid 10. The semiconductor chip 3 is connected onto the substrate 1. The case 4 houses the substrate 1 and the semiconductor chip 3. The sealing resin 8 seals the semiconductor chip 3 in the case 4. The lid 10 is disposed in the case 4 and covers the sealing resin 8 from the top thereof. The lid 10 includes a resin material 11 and carbon fibers 13 in a proportion of 10% by mass or more and 20% by mass or less of the entire lid 10.

The carbon fibers 13 have a higher thermal conductivity than the resin material 11. The thermal conductivity of PPS is 0.29 W/(m·K). On the other hand, the thermal conductivity of the carbon fibers 13 is 900 W/(m·K). Therefore, a lid 10 containing the carbon fibers 13 has a higher thermal conductivity than a lid 10 containing only the resin material 11. Therefore, the thermal conductivity of the lid 10 can be remarkably improved by containing the carbon fibers 13.

However, the carbon fibers 13 are likely to break when a large load is applied thereto. Such a load may be caused by a difference in the linear expansion coefficient between the resin material 11 and the carbon fibers 13. It is preferable to constrain the load caused by such a difference in the linear expansion coefficient to a level at which the carbon fibers 13 do not break. Therefore, it is preferable to appropriately control the content of the carbon fibers 13 with respect to the resin material 11. As described above, by containing the carbon fibers 13, the lid 10 can be manufactured to have sufficient heat dissipation. In addition, by containing the carbon fibers 13 at the above-described proportion, the lid 10 can be manufactured to have sufficient heat dissipation and can withstand a load caused by a difference in the linear expansion coefficient. Specifically, according to the present embodiment, the thermal conductivity of the lid can be improved by about 300 times to 600 times as compared to a lid made of only the resin material 11 and having the same shape and the same dimension.

### Fourth Embodiment

### <Configuration of Semiconductor Device>

FIG. 5 is a schematic view illustrating a lid according to the fourth embodiment in the state of a raw material. As illustrated in FIG. 5, the main component of the lid 10 of the present embodiment is a resin material 11. In the lid 10 of the present embodiment, the resin material 11 includes a filler 14. The filler 14 contains a polymer compound as a main component. The filler 14 has polarity. The lid 10 of the present embodiment may or may not contain the metal material 12 of the first and second embodiments.

In FIG. 5, each of the plurality of fillers 14 is a fine fiber extending in one direction. In FIG. 5, the plurality of fillers 14 extend randomly in completely different directions. FIG. 6 is a schematic view illustrating a lid after completion according to the fourth embodiment. In the raw material state illustrated in FIG. 5, an external force is applied to the plurality of fillers 14 dispersed in the resin material 11. Thereby, the orientation of the plurality of fillers 14 in the resin material 11 is changed. The external force is an electric field, a magnetic field, or the like. By applying an external force to the resin material 11 when molding the resin material 11, the fillers 14 in the lid 10 are arranged in such a manner that the molecules thereof are oriented in a predetermined direction as illustrated in FIG. 6.

In FIG. 6, as an example, the fillers 14 are arranged to extend substantially in the left-right direction. However, the fillers 14 are not limited to the orientation as illustrated in FIG. 6, and may be regularly arranged to extend in an oblique direction as illustrated in FIG. 6, for example. The fillers 14 may be arranged to extend along the thickness direction of the lid 10 (perpendicular to the paper surface of FIG. 6). In the state illustrated in FIG. 6, a large number of fine fillers 14 are spaced apart from each other and are uniformly dispersed in the resin material 11. A portion of the plurality of fillers 14 may be in contact with each other.

In the manufacturing process of the lid 10 of the present embodiment, a resin material 11 containing a small amount of polar fillers 14 may be prepared. If the resin material 11 does not contain the polar fillers 14, a small amount of the polar fillers 14 may be added to the resin material 11. Next, when the fillers 14 have anisotropy with respect to a magnetic field, an electric field or the like, an external force is applied to the fillers 14. Thereby, the molecules of the fillers 14 are oriented in a predetermined direction by the external force. The resin material 11 is cured while the external force is maintained. As a result, as illustrated in FIG. 6, the lid 10 in which the molecules are aligned in a predetermined direction is formed.

### <Effects>

The semiconductor device 100 according to the present embodiment includes a substrate 1, a semiconductor chip 3, a case 4, a sealing resin 8, and a lid 10. The semiconductor chip 3 is connected onto the substrate 1. The case 4 houses the substrate 1 and the semiconductor chip 3. The sealing resin 8 seals the semiconductor chip 3 in the case 4. The lid 10 is disposed in the case 4 and covers the sealing resin 8 from the top thereof. The main component of the lid 10 is a resin material 11. The resin material 11 includes a filler 14. The filler 14 has polarity, and the filler 14 is arranged in such a manner that the molecules thereof are oriented in a predetermined direction.

The higher the orientation degree of the molecules of the filler 14, the higher the thermal conductivity of the lid 10. Therefore, the heat dissipation of the entire semiconductor device 100 can be improved. From this viewpoint, the deviation of angle in the extending direction of each filler 14 included in the lid 10 is preferably 15° or less, and more preferably 10° or less. Further, the deviation of angle is more preferably 5° or less.

If the lid 10 is formed in such a manner that the molecules of the filler 14 are oriented in a predetermined direction as illustrated in FIG. 6, the thermal conductivity of the lid can be improved by about 4 to 6 times as compared to a lid in which the molecules of the filler are randomly oriented.

### Fifth Embodiment

### <Configuration of Semiconductor Device>

In the fourth embodiment, polyparaphenylene benzobisoxazole fibers (hereinafter referred to as PBO fibers) are used as the filler 14 in the lid 10. In the lid 10, the PBO fibers are contained in a proportion of 1% by mass or more and 4% by mass or less of the entire lid 10. In other words, the lid 10 is configured to contain the filler 14 in a proportion of 1% by mass or more and 4% by mass or less when the entire lid 10 is set to 100% by mass.

In the present embodiment, the filler 14 contained in the resin material 11 is preferably a liquid crystal polymer having a property of responding to an electric field or a magnetic field before being cured to form the lid 10. Therefore, any material other than the PBO fibers may be used as the filler 14. In other words, the filler 14 may be either p-phenylene terephthalamide or m-phenylene isophthalamide. In the case of either p-phenylene terephthalamide or m-phenylene isophthalamide, the filler 14 may be 1% by mass or more and 4% by mass or less of the entire lid 10.

The manufacturing process of the lid 10 of the present embodiment is basically the same as that of the fourth embodiment. For example, when the PBO fibers are used, the resin material 11 is prepared to contain a predetermined proportion of the PBO fibers. The PBO fibers have the property of changing orientation in response to a magnetic field. By utilizing this property, a magnetic field is applied to the resin material 11 in a liquid state. The resin material 11 is molded while maintaining the magnetic field.

### <Effects>

As described above, the semiconductor device 100 according to the present embodiment may contain PBO fibers as the filler 14 in a proportion of 1% by mass or more and 4% by mass or less of the entire lid 10. Thus, as in the fourth embodiment, the molecules of the PBO fibers (the filler 14) are oriented in a predetermined direction, which enhance the thermal conductivity of the lid 10. By increasing the orientation degree of the molecules of the PBO fibers, the thermal conductivity of the lid can be improved by about 2 to 5 times as compared to a lid made of only the resin material 11 and having the same shape and the same dimension.

By containing the PBO fibers in the lid 10, the lid 10 can be manufactured to have sufficient heat dissipation. In addition, by containing the PBO fibers in the above proportion, the lid 10 can be manufactured to have sufficient heat dissipation at low cost.

The configurations described in (each example included in) each embodiment described above may be appropriately combined as long as they are not technically contradictory to each other.

Although the embodiments of the present invention have been described, it should be understood that the embodiments disclosed herein are illustrative and non-restrictive in all respects. It is intended that the scope of the present invention is not limited to the description above but defined by the scope of the claims and encompasses all modifications equivalent in meaning and scope to the claims.

What is claimed is:

1. A semiconductor device comprising:
a substrate;
a semiconductor element that is connected onto the substrate;
a case that houses the substrate and the semiconductor element;
a sealing resin that seals the semiconductor element in the case; and
a lid that is disposed in the case and covers the sealing resin from the top thereof,
the lid being made of both a resin material and a metal material mixed in the resin material.

2. The semiconductor device according to claim 1, wherein
the lid contains at least one of copper and aluminum in a proportion of 10% by mass or more and 30% by mass or less of the entire lid.

3. A semiconductor device comprising:
a substrate;
a semiconductor element that is connected onto the substrate;
a case that houses the substrate and the semiconductor element;
a sealing resin that seals the semiconductor element in the case; and
a lid that is disposed in the case and covers the sealing resin from the top thereof,
the lid containing a resin material and carbon fibers in a proportion of of 10% by mass or more and 20% by mass or less of the entire lid.

4. A semiconductor device comprising:
a substrate;
a semiconductor element that is connected onto the substrate;
a case that houses the substrate and the semiconductor element;
a sealing resin that seals the semiconductor element in the case; and
a lid that is disposed in the case and covers the sealing resin from the top thereof,
the main component of the lid being a resin material,
the resin material including a filler,
the filler having polarity, and the filler being arranged in such a manner that the molecules thereof are oriented in a predetermined direction.

5. The semiconductor device according to claim 4, wherein
the filler contains polyparaphenylene benzobisoxazole fibers in a proportion of 1% by mass or more and 4% by mass or less of the entire lid.
